(19) United States
(12) Patent Application Publication
(10) Pub. No.: US 2016/0054352 A1
(43) Pub. Date: Feb. 25, 2016

(54) MULTI-AXIS SENSOR AND METHOD FOR MANUFACTURING THE SAME

(71) Applicants: SAMSUNG ELECTRO-MECHANICS CO., LTD., Suwon-Si (KR); TOHOKU UNIVERSITY, Sendai-shi (JP)

(72) Inventors: Pil Joong KANG, Suwon-Si (KR); Je Hong KYOUNG, Suwon-Si (KR); Masayoshi ESASHI, Aoba-ku (JP); Jung Won LEE, Suwon-Si (KR)

(73) Assignees: SAMSUNG ELECTRO-MECHANICS CO., LTD., Suwon-Si (KR); TOHOKU UNIVERSITY, Sendai-shi (JP)

(21) Appl. No.: 14/590,994

(22) Filed: Jan. 7, 2015

(30) Foreign Application Priority Data
Aug. 25, 2014 (KR) 10-2014-0111002

(51) Int. Cl. G01P 15/12; G01R 33/12; H01L 43/00; H01L 41/23; H01L 41/113; G01P 15/14; G01L 9/00

(52) U.S. Cl. CPC G01P 15/123; G01P 15/14; G01R 33/12; G01L 9/00; H01L 41/23; H01L 41/1132; H01L 43/00

(57) ABSTRACT

There are provided a multi-axis sensor and a method for manufacturing the same. The multi-axis sensor includes: a first sensor mounted on a board and detecting inertial force; and a second sensor mounted on the board and detecting a position and a motion, wherein the first sensor and the board have a seal formed therebetween so as to prevent permeation from the outside and are electrically connected to each other.

### CROSS-REFERENCE TO RELATED APPLICATION

This application claims the benefit of Korean Patent Application No. 10-2014-0111002, filed on Aug. 25, 2014, entitled “Multi-axis Sensor and Method for Manufacturing the Same” which is hereby incorporated by reference in its entirety into this application.

### BACKGROUND

The present disclosure relates to a multi-axis sensor and a method for manufacturing the same.

Electronic components included in mobile electronics such as cellular phone, a tablet personal computer (PC), and the like, have two important indices (competition objects). One object is miniaturization competition allowing the electronic components to have a smaller size while having the same or more excellent performance. In addition, the other object is minimum power consumption.

Among the electronic components, various sensors such as an angular velocity sensor, an acceleration sensor, a terrestrial magnetism sensor, a pressure sensor, and the like, sense the respective corresponding information and provide the sensed information, as described in the following Patent Document (Korean Patent No. 10-0855471).

As described above, each information of various sensors may be utilized as information required for functions of the mobile electronics. However, in order to provide various and complicated functions to users of the mobile electronics, information of various sensors needs to be comprehensively calculated so as to be utilized as the information required for the functions of the mobile electronics. Therefore, recently, the use of a multi-axis sensor in which various sensors are integrated with each other has gradually increased.

In addition, recently, a method for appropriately designing and manufacturing the multi-axis sensor capable of decreasing power consumption in a scheme of judging that various sensors are one integration information processing devices and driving only required sensors in a required time to obtain information has been demanded.

### RELATED ART DOCUMENT

### Patent Document

(Patent Document 1) KR10-0855471 B

### SUMMARY

An aspect of the present disclosure may provide a multi-axis sensor capable of being miniaturized and decreasing power consumption by an improved structure and manufacturing method, and a method for manufacturing the same.

According to an aspect of the present disclosure, a multi-axis sensor may include: a first sensor directly formed in a predetermined region on a board and detecting inertial force; and a second sensor mounted on the board and detecting a position and a motion, wherein the first sensor and the board are sealed so as to prevent permeation from the outside and are electrically connected to each other.

In addition, the multi-axis sensor may be manufactured at a compact size, and a compact multi-axis sensor may improve electrical efficiency.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of a multi-axis sensor according to an exemplary embodiment of the present disclosure;

FIG. 2 is a side view of the multi-axis sensor viewed from side A of FIG. 1;

FIG. 3 is a side view of the multi-axis sensor viewed from side B of FIG. 1;

FIG. 4 is a view showing a method for forming a first sensor according to an exemplary embodiment of the present disclosure;

FIG. 5 is a view showing a method for forming a terrestrial magnetism sensor of a second sensor according to an exemplary embodiment of the present disclosure;

FIG. 6 is a view showing a method for forming a pressure sensor of the second sensor according to an exemplary embodiment of the present disclosure;

FIG. 7 is a plan view showing a form in which the first sensor and the terrestrial magnetism sensor according to an exemplary embodiment of the present disclosure are mounted on a board;

FIG. 8 is a side view showing a method for forming the second sensor according to an exemplary embodiment of the present disclosure;

FIGS. 9A to 9E are views showing a process for manufacturing a multi-axis sensor according to an exemplary embodiment of the present disclosure;

FIG. 10 is a schematic cross-sectional view of a multi-axis sensor according to an exemplary embodiment of the present disclosure in which first and second sensors are electrically connected to each other on a board;

FIG. 11 is a schematic cross-sectional view of a multi-axis sensor according to a second exemplary embodiment of the present disclosure in which first and second sensors are electrically connected to each other on an application specific integrated circuit; and

FIG. 12 is a schematic cross-sectional view of a multi-axis sensor according to a third exemplary embodiment of the present disclosure in which first and second sensors are electrically connected to each other on a low temperature co-fired ceramic.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

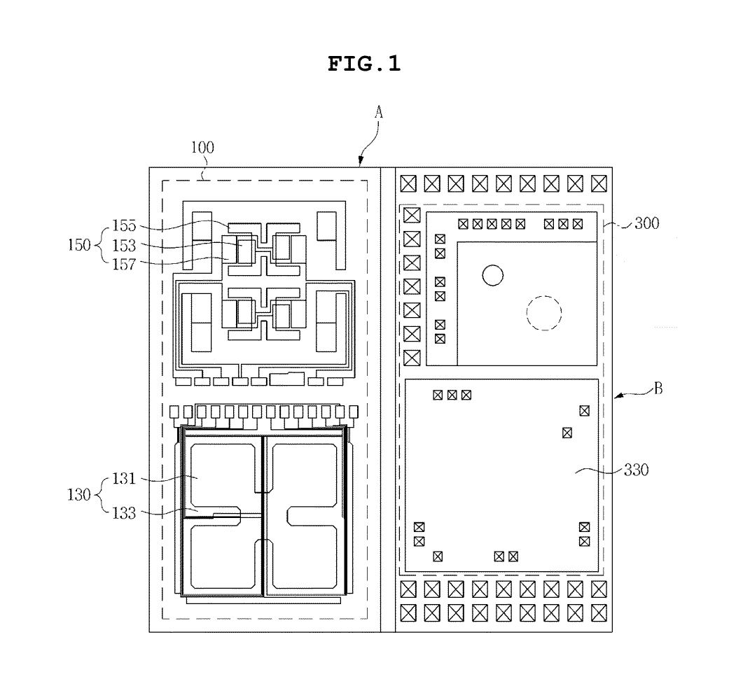

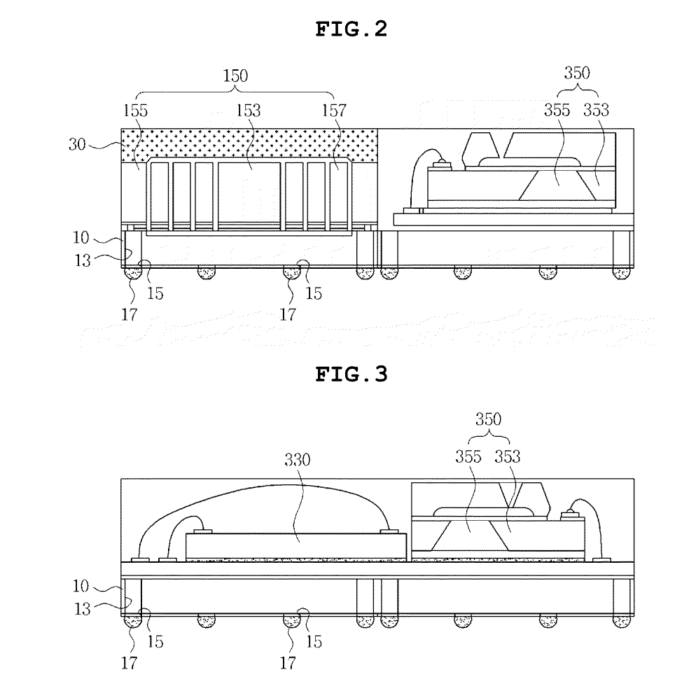

FIG. 1 is a diagram illustrating a camera module of an auto focus function to which an apparatus for driving a voice coil motor actuator according to a first exemplary embodiment of the present disclosure is applied and FIG. 2 is a diagram illustrating the apparatus for driving a voice coil motor actuator according to the first exemplary embodiment of the present disclosure.

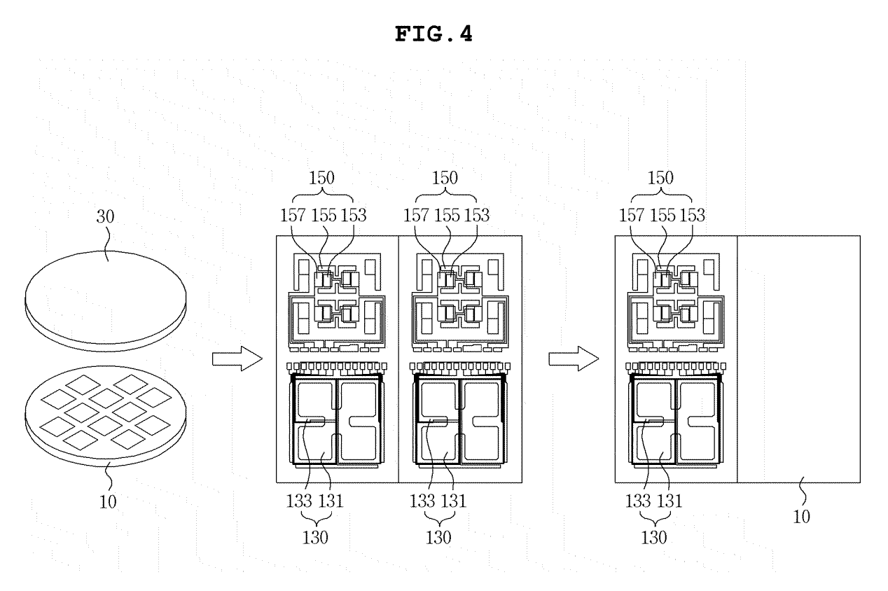

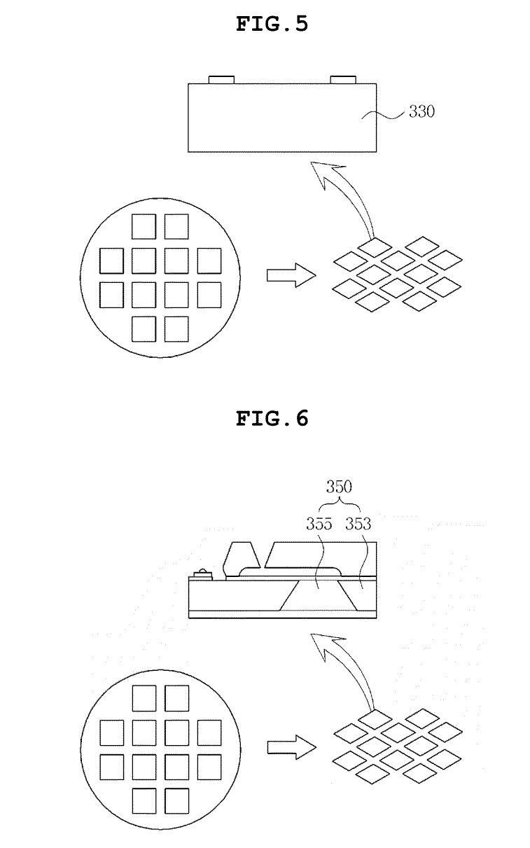

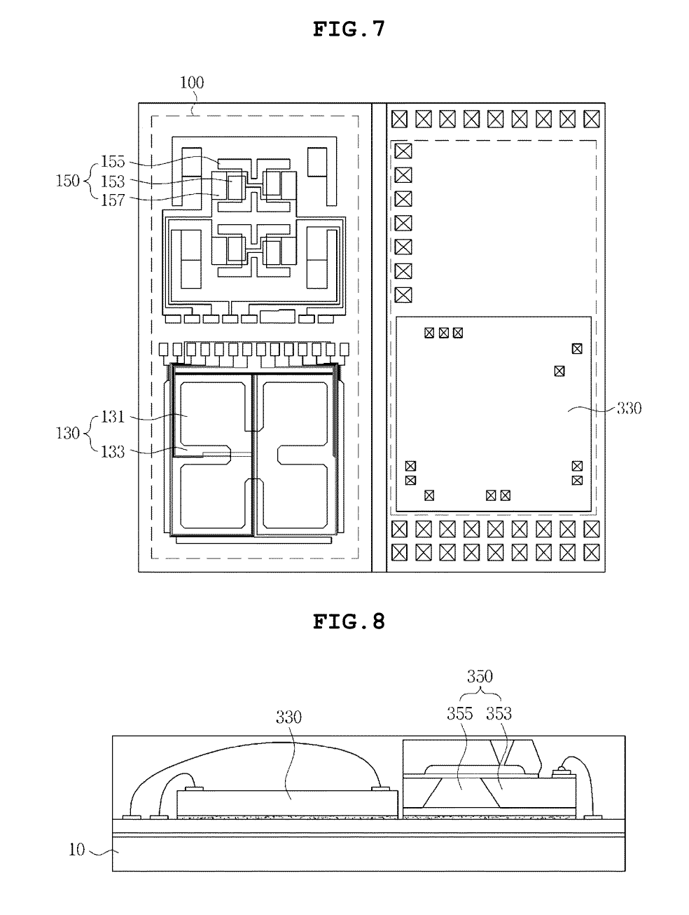

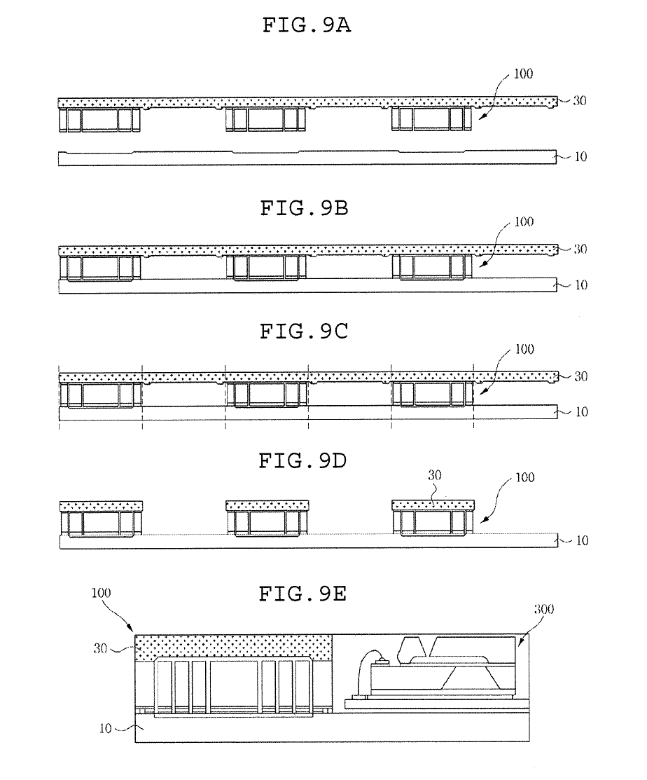

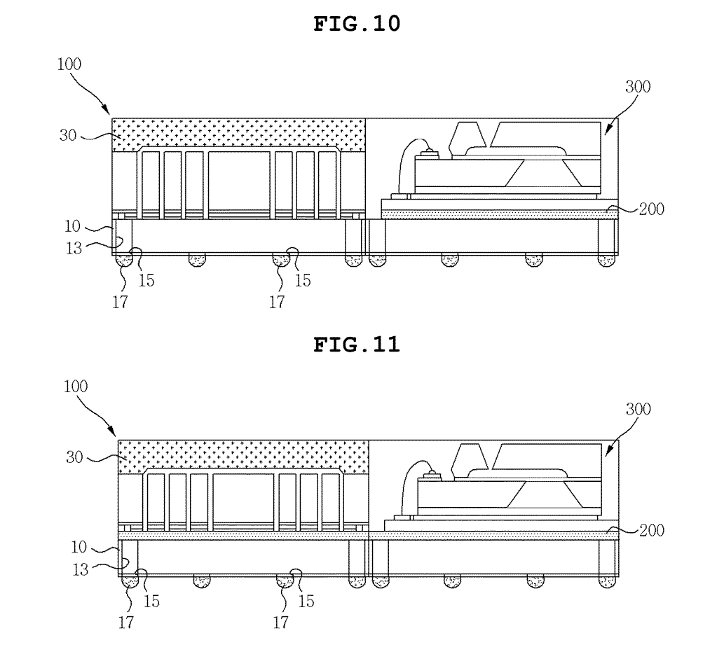

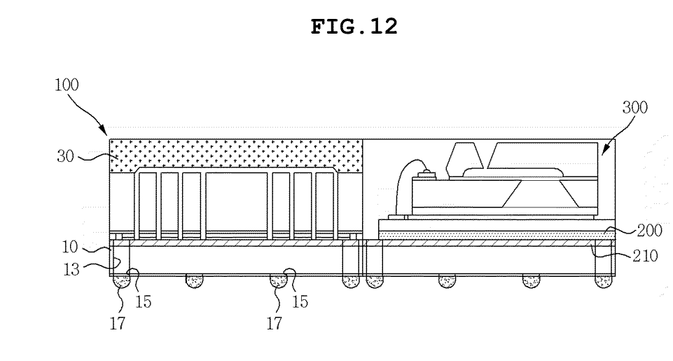

FIG. 1 is a plan view of a multi-axis sensor according to an exemplary embodiment of the present disclosure; FIG. 2 is a side view of the multi-axis sensor viewed from side A of FIG. 1; FIG. 3 is a side view of the multi-axis sensor viewed from side B of FIG. 1; FIG. 4 is a view showing a method for forming a first sensor according to an exemplary embodiment of the present disclosure; FIG. 5 is a view showing a method for forming a terrestrial magnetism sensor of a second sensor according to an exemplary embodiment of the present disclosure; FIG. 6 is a view showing a method for forming a pressure sensor of the second sensor according to an exemplary embodiment of the present disclosure; FIG. 7 is a plan view showing a form in which the first sensor and the terrestrial magnetism sensor according to an exemplary embodiment of the present disclosure are mounted on a board; FIG. 8 is a side view showing a method for forming the second sensor according to an exemplary embodiment of the present disclosure; FIGS. 9A to 9E are views showing a process for manufacturing a multi-axis sensor according to an exemplary embodiment of the present disclosure; FIG. 10 is a schematic cross-sectional view of a multi-axis sensor according to an exemplary embodiment of the present disclosure in which first and second sensors are electrically connected to each other on a board; FIG. 11 is a schematic cross-sectional view of a multi-axis sensor according to a second exemplary embodiment of the present disclosure in which first and second sensors are electrically connected to each other on an application specific integrated circuit; and FIG. 12 is a schematic cross-sectional view of a multi-axis sensor according to a third exemplary embodiment of the present disclosure in which first and second sensors are electrically connected to each other on a low temperature co-fired ceramic.

First and second sensors and a board according to an exemplary embodiment of the present disclosure will be described in detail. Referring to FIGS. 1 to 3, the first sensor 100 is a six-axis inertial sensor including an acceleration sensor 130 and an angular velocity sensor 150. The first sensor 100 is formed on the board 10 in a wafer level package (WLP) scheme. The first sensor 100 is formed using the board 10 and a cap 30 to be described below in the wafer level package (WLP) scheme.

The first sensor 100 has a seal space formed therein in order to block fine dust, dust, moisture, or the like. The first sensor 100 is formed so as to seal each of the board 10 and the cap 30. That is, a lower surface of the first sensor 100 seals the board 10, and an upper surface of the first sensor 100 seals the cap 30 (See FIG. 2).

The six-axis inertial sensor, which is the first sensor 100, prevents air, dust, particles, moisture, or the like, from penetrating thereinto due to a seal space of the board 10 and the cap 30. It is preferable that the seal space of the first sensor 100 is a hermetic seal space. However, the seal space of the first sensor 100 is not limited to the hermetic seal space.

The acceleration sensor 130, which is a three-axis sensor measuring accelerations of X, Y, and Z axes, senses liner movement. As the acceleration sensor 130, a sensor having high resolving power and a small size is used in order to detect a fine acceleration. The acceleration sensor 130 includes a mass body part 131 and a flexible beam part 133 connected to the mass body part 131 (See FIG. 1).

The acceleration sensor 130 converts movement of the mass body part 131 or the flexible beam part 133 into an electrical signal. When an acceleration is applied to the acceleration sensor 130 by external force, the mass body part 131 of the acceleration sensor 130 is displaced, and resistance signals of the flexible beam part 133 of the acceleration sensor 130 are changed. Here, electric resistance signals of piezo resistor elements (not shown) of the flexible beam part 133 are changed. That is, a potential difference generated due to a difference between resistance change amounts is extracted and is sensed as an acceleration value.

The angular velocity sensor 130 includes four piezo resistor elements for sensing the acceleration. The piezo resistor elements (not shown) of the flexible beam part 133 extracts the potential difference generated by a difference between change amounts of the resistance signals to sense the acceleration value. The acceleration sensor 130 includes wirings formed therein in order to electrically connect the flexible beam part 133 and the piezo resistor elements to each other.

The flexible beam part 133, which is to support the mass body part 131, includes first to fourth flexible beam parts each formed around the mass body part 131. For example, a piezo resistor element for sensing the acceleration in the X axis is formed at an end portion of the first flexible beam part, and a piezo resistor element for sensing the acceleration in the Z axis is formed at an end portion of the second flexible beam part, such that the first flexible beam part and the second flexible beam part may sense the accelerations in X and Z axis directions. In addition, the third flexible beam part and the fourth flexible beam part each disposed perpendicularly to the first flexible beam part and the second flexible beam part are provided with semiconductor piezo resistor elements for sensing the acceleration of the Y axis, thereby making it possible to sense the acceleration in a Y axis direction.

The angular velocity sensor 150 is formed on an upper surface of the board 10. The angular velocity sensor 150 is a three-axis sensor measuring angular velocities in the X, Y, and Z axes. That is, the angular velocity sensor 150 senses movement in the X, Y, and Z axes. The angular velocity sensor 150 needs to have high resolving power and a small size in order to detect a fine angular velocity.

The angular velocity sensor 150 includes a sensor mass body 153, a frame 155, and a flexible part 157 (See FIGS. 1 and 2). The sensor mass body 153 is displaced by Coriolis force. The sensor mass body 153 includes first and second mass bodies having the same size and shape. The first and second mass bodies generally have a square pillar shape. The first and second mass bodies are not limited to having the square pillar shape, but may have all shapes known in the art. Flexible parts are connected to the first and second mass bodies, respectively. The first and second mass bodies are formed so as to be supported by the frame 155.

The frame 155 may have the sensor mass body 153 disposed therein and is connected to the sensor mass body 153 by the flexible part 157. The frame 155 secures a space in which the first and second mass bodies connected to each other by the flexible part 157 may be displaced, respectively. The frame 155 may be formed as the same thickness as that of the flexible part 157. In addition, the frame 155 is formed so as to cover only a portion of the sensor mass body 153. The frame 155 has a cavity formed at the center thereof, wherein the cavity has a square pillar shape. However, this is not to limit a shape of the frame 155.

The flexible part 157 may include a sensing means sensing angle displacement of the sensor mass body 153. The flexible part 157 measures vibration displacement of the sensor mass body 153. The flexible part 157 may be disposed at a position spaced apart from the center of the sensor mass body 153 by a predetermined distance. The sensing means of the flexible part 157 may use a piezoelectric scheme, a piezoresistive scheme, a capacitive scheme, an optical scheme, or the like, but is not particularly limited thereto.

The cap 30 is adjacent to the angular velocity sensor 150 and the acceleration sensor 130 and is formed at upper end portions of the angular velocity sensor 150 and the acceleration sensor 130. The cap 30 protects an inner portion from external impact. The cap 30 may be formed of a low temperature co-fired ceramic (LTCC), a glass, an interposer, and a silicon having a penetration hole formed therein, so as to have sealing force.

The second sensor 300 includes a terrestrial magnetism sensor 330 and a pressure sensor 350 each formed in a system-in-package (SIP) scheme.

The terrestrial magnetism sensor 330, which is a three-axis sensor, measures and senses strength of an Earth's magnetic field. The terrestrial magnetism sensor 330 may be configured of one chip using a micro electro mechanical systems (MEMS) technology. The terrestrial magnetism sensor 330 may use three independent sensors such as a hall sensor, a magneto-resistance (MR) sensor, a magneto-impedance (MI) sensor, and the like.

The pressure sensor 350 measures atmospheric pressure for generating an electrical signal depending on external pressure to find out a current altitude. The pressure sensor 350 includes a sensing part formed by etching a lower portion of a single crystal silicon 353 having a surface. The pressure sensor 350 may also include a piezoresistor formed on the single crystal silicon 353. In addition, the pressure sensor 350 may include a molding in which an open hole is formed.

FIG. 10 is a schematic cross-sectional view of a multi-axis sensor according to an exemplary embodiment of the present disclosure in which first and second sensors are electrically connected to each other on a board. A structure of the multi-axis sensor according to an exemplary embodiment of the present disclosure in which the first and second sensors are electrically connected to each other on the board will be described in detail with reference to FIG. 10.

The board 10 supports the first and second sensors 100 and 300. The board 10 provides regions in which the first and second sensors 100 and 300 are mounted. Here, in the board 10, areas of the regions in which the first and second sensors 100 and 300 are formed are the same as or different from each other. The board 10 may be fixed or electrically connected to another board using solder ball pads 15 and solder balls 17.

The board 10 electrically connects the first and second sensors 100 and 300 to each other. The board 10 may be formed using a low temperature co-fired ceramic (LTCC), a glass, an interposer, an application specific integrated circuit (ASIC), a silicon, and the like.

The board 10 has wirings formed on a surface thereof, wherein the wirings have predetermined patterns. That is, the patterns of the board 10 electrically connect vertically and horizontally the first and second sensors 100 and 300 to each other. The board 10 may be a silicon interposer board. The board 10 may be used singly or together with an application specific integrated circuit 200, a low temperature co-fired ceramic (LTCC) 210, and the like, to be described below.

It is preferable that the upper surface of the board 10 is formed so that the first sensor 100 is mounted thereon. The first sensor 100 is electrically mounted on the upper surface of the board 10 while sealing the upper surface of the board 10. When the first sensor 100 seals the upper surface of the board 10, a height of the multi-axis sensor may be decreased.

The first sensor 100 is mounted on the surface of the board 10, such that the number of caps 30 formed at upper and lower portion of the first sensor in order to process the first sensor 100 in the wafer level package (WLP) scheme is decreased from two to one. One cap 30 is formed, such that a material cost and a process cost required for a process may be decreased. In addition, one cap 30 is formed so as to electrically connect the board 10 and the first sensor 100 to each other. An entire height of the board 10 and the first sensor 100 may be decreased. That is, as a height and an area of the multi-axis sensor are decreased, power consumption of the multi-axis sensor may be decreased.

It is preferable that the first sensor 100 seals the upper surface of the board 10 by hermetic seal bonding. However, this is not to limit a method in which the first sensor 100 seals the upper surface of the board 10 to the hermetic seal bonding.

FIG. 11 is a schematic cross-sectional view of a multi-axis sensor according to a second exemplary embodiment of the present disclosure in which an application specific integrated circuit is formed on a board and first and second sensors are electrically connected to each other on the application specific integrated circuit. A structure of the multi-axis sensor according to a second exemplary embodiment of the present disclosure in which the first and second sensors are electrically connected to each other on the application specific integrated circuit will be described in detail with reference to FIG. 11.

The application specific integrated circuit (ASIC) 200 supports the first and second sensors 100 and 300. The ASIC 200 provides regions in which the first and second sensors 100 and 300 are mounted. Here, in the ASIC 200, areas of the regions in which the first and second sensors 100 and 300 are formed are the same as or different from each other. The ASIC 200 may be fixed or electrically connected to another board using solder ball pads 15 and solder balls 17.

The ASIC 200 electrically connects the first and second sensors 100 and 300 to each other. The ASIC 200 is formed so as to connect lower surfaces of the first and second sensors 100 and 300 integrally with each other. In addition, the ASIC 200 may be inserted into an upper surface or an inner portion of the board 100. The ASIC 200 electrically connects the first and second sensors 100 and 300 to each other.

In addition, the ASIC 200 may also transfer an electrical signal to the first and second sensors 100 and 300 through the board 10. The ASIC 200 may be connected to the board 10 to electrically connect the first and second sensors 100 and 300 to each other.

The ASIC 200 electrically connects the first and second sensors 100 and 300 to each other in various forms. The ASIC 200 may use a via, a through-hole, and the like, when it is connected to the board 10.

The ASIC 200 simultaneously or individually seals the first and second sensors 100 and 300. It is preferable that hermetic seal bonding is used when the ASIC 200 seals the first and second sensors 100 and 300. However, this is not to limit a method in which the ASIC 200 seals the first and second sensors 100 and 300 to the hermetic seal bonding.

The pressure sensor 350 and the terrestrial magnetism sensor 330 of the second sensor 300 may be electrically connected to each other using the AISC 200. The ASIC 200 is formed so as to contact the upper surface of the board 10. The ASIC 200 is an application specific integrated circuit and a substrate. That is, the ASIC 200 is an application specific integrated circuit and a substrate, which is a special semiconductor ordered by a user and designed and manufactured by a semiconductor manufacturer depending on the order. Therefore, a predetermined pattern is formed on the ASIC 200 or various patterns are formed on the ASIC 200 depending on a demand of the user. Since the ASIC 200 satisfies various demands of the user, importance of an ASIC technology in a semiconductor industry has been recently increased rapidly.

FIG. 12 is a schematic cross-sectional view of a multi-axis sensor according to a third exemplary embodiment of the present disclosure in which a low temperature co-fired ceramic is formed on a board and first and second sensors are electrically connected to each other on the low temperature co-fired ceramic. A structure of the multi-axis sensor according to a third exemplary embodiment of the present disclosure in which the board, the ASIC, and the first and second sensors are electrically connected to each other will be described in detail with reference to FIG. 12.

The low temperature co-fired ceramic (LTCC) 210 electrically connects the first and second sensors 100 and 300 to each other. The LTCC 210 is formed so as to connect lower surfaces of the first and second sensors 100 and 300 integrally with each other. The LTCC 210 is formed by stacking several sheets of ceramics. Here, the LTCC 210 may include penetration wirings formed in a stacked board and may be hermetically sealed since a ceramic itself is a hermetic material. That is, the reason is that silicon anodic bonding is possible while forming vertical and horizontal penetration wirings in the LTCC 210, such as a hermetic seal is possible.

The LTCC 210 serves as a cap on a lower surface of the first sensor 100 and serves a wiring so that electricity is vertically conducted (See FIG. 12). That is, the LTCC 210 serves as a silicon interposer.

The LTCC 210 may be inserted into an upper surface or an inner portion of the board 10. The LTCC 210 connects lower surfaces of the first and second sensors 100 and 300 integrally with each other and electrically connects the first and second sensors 100 and 300 to each other.

The LTCC 210 may be formed in only one of the first and second sensors 100 and 300 and be connected to the board 10 to electrically connect the first and second sensors 100 and 300 to each other. In addition, the LTCC 210 may have the ASIC 200 separately formed thereon and electrically connect the ASIC 200 to the first and second sensors 100 and 300. The LTCC may electrically connect the first and second sensors 100 and 300 in various forms.

It is preferable that the ASIC 200 is formed on a surface of the LTCC 210 and a lower surface of the second sensor 300. Here, when the ASIC 200 is hermetic-seal-bonded to a lower portion of the first sensor 100 using a cap, a manufacturing cost is increased at the time of forming penetration wirings in the ASIC 200 through a via, a through-hole, and the like.

In addition, the penetration wirings and a hermetic seal are already formed in the ASIC 200. Therefore, there is no need to again manufacture the hermetic seal using the LTCC 210. That is, the hermetic seal does not need to be manufactured doubly.

The LTCC 210 seals the first sensor 100. The LTCC 210 seals the first sensor 100 using hermetic seal bonding. However, this is not to limit a method in which the LTCC 210 seals the first sensor 100 to the hermetic seal bonding.

The LTCC may be electrically connected to the ASIC 200. The LTCC may use a via, a through-hole, and the like, when it is connected to the board 10.

Hereinafter, a method for manufacturing a multi-axis sensor according to an exemplary embodiment of the present disclosure will be described in more detail.

Referring to FIGS. 4 to 9, the method for manufacturing a multi-axis sensor according to an exemplary embodiment of the present disclosure includes: preparing a board; forming a first sensor on the board in a wafer level package (WLP) scheme; forming a seal space at the time of forming the first sensor and the board; and forming a second sensor on the board in a system-in-package (SIP) scheme.

The board 10 is prepared. The board 10 may be formed using any one of a low temperature co-fired ceramic (LTCC), a glass, an interposer, an application specific integrated circuit (ASIC), and a silicon. It is preferable that the board 10 is formed using the ASIC, the LTCC, the glass, or the like. In addition, the board 10 may also be used on a lower surface for electrical wirings of the ASIC and the LTCC described above.

As the first sensor 100, a six-axis inertial sensor including the acceleration sensor 130 and the angular velocity sensor 150 is prepared. The first sensors 100 are formed on the board 10 in the WLP scheme.

The first sensor 100 is disposed so as to maintain a predetermined distance from the cap 30 (See FIG. 9A). Here, a lower end of the first sensor 100 is coupled to the board 10. The first sensor 100 and the cap 30 form a seal space. The seal space is used to allow the acceleration sensor 130 and the angular velocity sensor 150 to be the six-axis inertial sensor.

The seal space is formed at the time of bonding the first sensor 100 and the board 10 to each other (See FIG. 9B). The seal space is used to allow the acceleration sensor 130 and the angular velocity sensor 150 to be the six-axis inertial sensor. In addition, the seal space may be used as a reference line for cutting the first sensor 100. The first sensor 100 and the board 10 are electrically connected to each other.

It is preferable that the first sensor 100 is formed in a range of about 40 to 60% with respect to an area of the board 10. The six-axis inertial sensor is generally formed so as to have an area wider than that of the second sensor 300. Therefore, the six-axis inertial sensor and the second sensor 300 have different areas. However, this is not to limit areas (sizes) of the first and second sensors 100 and 300.

The cap 30 is removed at portions except for portions at which the first sensors 100 and the cap 30 are bonded to each other (See FIGS. 9C and 9D). This is to couple the second sensor to the board in the removed space.

The first sensor 100 and the cap 30 are formed so as to have the seal space therebetween. The cap 30 is cut based on the first sensor. The board 10 is cut based on the first sensor 100 (See FIG. 9D). In the method for manufacturing a multi-axis sensor, the board 10 may be first formed depending on a disposition form of the first sensor 100. That is, a sequence in which the board 10 and the cap 30 are formed at the first sensor 100 may be changed.

A three-axis terrestrial magnetism sensor 330 is formed in the SIP scheme (See FIG. 5). A one-axis pressure sensor 350 is formed in the SIP scheme (See FIG. 6). The second sensor 300 is formed on the board 10 in the SIP scheme (See FIG. 7). The second sensor includes the terrestrial magnetism sensor 330 and the pressure sensor 350. The terrestrial magnetism sensor 330 and the pressure sensor 350 are mounted on the board 10 in the SIP scheme, respectively (See FIG. 8).

The terrestrial magnetism sensor 330 and the pressure sensor 350 mounted on the board 10 are electrically connected to each other. That is, the terrestrial magnetism sensor 330 and the pressure sensor 350 are electrically connected to each other using a metal wire. However, this is not to limit a method for connecting among the board, the terrestrial magnetism sensor 330, and the pressure sensor 350. A plastic package process for molding a metal can, an epoxy, or the like, which is a subsequent process of the electrical connection process, is performed. In addition, the solder ball pads 15 and the solder balls 17 for connection may be formed at a lower end portion of the board 10.

In the method for manufacturing a multi-axis sensor according to an exemplary embodiment of the present disclosure, after the first sensor 100, which is the six-axis inertial sensor having the hermetic seal, is directly formed on the board in the WLP scheme, the second sensors 300 including the three-axis terrestrial magnetism sensor 330 and one-axis pressure sensor 350 formed in the SIP scheme is mounted at one side of the first sensor 100 on the board 10, thereby making it possible to miniaturize the multi-axis sensor and decrease power consumption of the multi-axis sensor.

That is, in the method for manufacturing a multi-axis sensor according to an exemplary embodiment of the present disclosure, since a required area of the first sensor 100 may be decreased by directly forming the first sensor 100 on the board in the WLP scheme, a size of the multi-axis sensor is decreased as compared with a multi-axis sensor formed by forming both of the first and second sensors 100 and 300 in the SIP scheme and then mounting each of the first and second sensors 100 and 300 on the board, such that miniaturization of the multi-axis sensor may be accomplished and space utilization may be improved.

Here, the multi-axis sensor formed by forming both of the first and second sensors 100 and 300 in the SIP scheme has a limitation in decreasing a size thereof due to a required area, or the like, of each sensor formed in the SIP scheme.

In addition, in the method for manufacturing a multi-axis sensor according to an exemplary embodiment of the present disclosure, the first sensor 100, which is the six-axis inertial sensor having the hermetic seal, is directly formed on the board in the WLP scheme, such that the number of manufacturing processes may be decreased as compared with a six-axis sensor formed by forming the first and second sensors in the SIP scheme and then mounting the first and second sensors on the board. Therefore, the multi-axis sensors may be produced at a low cost and be collectively mass-produced, such that productivity may be improved. Here, in the case of the multi-axis sensor formed by forming both of the first and second sensors 100 and 300 in the SIP scheme, the individually manufactured sensors are mounted on the board such as a printed circuit board (PCB), or the like, using die bonding, or the like, are electrically connected to each other through wire bonding, and are then manufactured as one module using a metal can or a plastic package. In the case of the multi-axis sensor as described above, a manufacturing cost of a package process for mounting the respective sensors and connecting the respective sensors to each other is high, for example, works of individual packages are required, such that a package cost is increased, and a throughput of the package process is slow, such that it is difficult to mass product the multi-axis sensor.

In addition, in the method for manufacturing a multi-axis sensor according to an exemplary embodiment of the present disclosure, the first sensor 100 may be directly formed on the ASIC 200. The first and second sensors 100 and 300 are directly mounted on the ASIC 200, such that the first and second sensors 100 and 300 may be disposed adjacently to the ASIC 200. Therefore, the multi-axis sensor may be miniaturized and power consumption of the multi-axis sensor may be decreased.

Further, in the method for manufacturing a multi-axis sensor according to an exemplary embodiment of the present disclosure, the first sensors 100 having the hermetic seal are directly formed on the board in the WLP scheme, such that the first sensors 100 may be mass-produced at a low cost and be miniaturized, and reliability for performance of the hermetic seal may be improved.

Further, a six-axis inertial sensor may be formed in a partial region (for example, a half region) of a common board to which a WLP process is applied through the method for manufacturing a multi-axis sensor according to an exemplary embodiment of the present disclosure. The method for manufacturing a multi-axis sensor according to an exemplary embodiment of the present disclosure may be applied to a WLP process of a board that may have a structure of an asymmetric area ratio (multiple area).

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A multi-axis sensor comprising:
a first sensor mounted on a board and detecting inertial force; and
a second sensor mounted on the board and detecting a position and a motion,
wherein the first sensor and the board have a seal formed therebetween so as to prevent permeation from the outside and are electrically connected to each other.

2. The multi-axis sensor of claim 1, wherein the seal is formed by hermetic seal bonding, and
the first and second sensors are electrically connected to each other.

3. The multi-axis sensor of claim 2, wherein the first sensor has a seal formed thereon using a cap.

4. The multi-axis sensor of claim 3, wherein the first sensor and the cap are formed by hermetic seal bonding.

5. The multi-axis sensor of claim 3, wherein the board is formed using anyone of a low temperature co-fired ceramic (LTCC), a glass, an interposer, an application specific integrated circuit (ASIC), and a silicon so as to conduct electricity.

6. The multi-axis sensor of claim 3, wherein the first sensor is coupled to the board in a wafer level package (WLP) scheme, and
the second sensor is coupled to the board in a system-in-package (SIP) scheme.

7. The multi-axis sensor of claim 6, wherein the first sensor is formed of an inertial sensor including an acceleration sensor and an angular velocity sensor.

8. The multi-axis sensor of claim 7, wherein the first sensor includes at least one hermetic seal.

9. The multi-axis sensor of claim 8, wherein the second sensor includes a terrestrial magnetism sensor and a pressure sensor each formed on the board in the SIP scheme.

10. The multi-axis sensor of claim 9, wherein the first and second sensors have an ASIC formed integrally therewith at lower end portions thereof, the ASIC being formed so as to electrically connect the first and second sensors to each other.

11. The multi-axis sensor of claim 9, wherein the first or second sensor has an ASIC formed at a lower end portion thereof, the ASIC being electrically connected to the board so as to electrically connect the first and second sensors to each other.

12. The multi-axis sensor of claim 9, wherein the first and second sensors include an LTCC formed integrally therewith at lower end portions thereof, the LTCC being formed so as to electrically connect the first and second sensors to each other.

13. The multi-axis sensor of claim 12, wherein the LTCC is formed of a material by which anodic bonding is performed, and
the LTCC is formed so as to form a hermetic seal together with the first sensor.

14. A method for manufacturing a multi-axis sensor, comprising:
preparing a board;
forming a first sensor on the board in a WLP scheme;
forming a seal space at the time of forming the first sensor and the board; and
forming a second sensor on the board in an SIP scheme.

15. The method for manufacturing a multi-axis sensor of claim 14, wherein in the forming of the seal space at the time of forming the first sensor and the board, a hermetic seal space is formed as the seal space, and the first sensor and the board are electrically connected to each other.

16. The method for manufacturing a multi-axis sensor of claim 14, wherein in the preparing of the board, the board is prepared using anyone of an LTCC, a glass, an interposer, an ASIC, and a silicon.

17. The method for manufacturing a multi-axis sensor of claim 14, wherein in the forming of the first sensor on the board in the WLP scheme, the first sensor is formed in a range of 40 to 60% with respect to an area of the board.

18. The method for manufacturing a multi-axis sensor of claim 17, wherein in the forming of the first sensor on the board in the WLP scheme, the first sensor is formed of an inertial sensor including an acceleration sensor and an angular velocity sensor.

19. The method for manufacturing a multi-axis sensor of claim 14, wherein in the forming of the second sensor on the board in the SIP scheme, the second sensor is formed so as to include a terrestrial magnetism sensor and a pressure sensor.
